(19) United States
(12) Patent Application Publication
(10) Pub. No.: US 2022/0255508 A1
(43) Pub. Date: Aug. 11, 2022

(54) LOAD MODULATED DOHERTY POWER AMPLIFIERS

(71) Applicant: Skyworks Solutions, Inc., Irvine, CA (US)

(72) Inventors: Philip John Lehtola, Cedar Rapids, IA (US); Bo Pan, Irvine, CA (US); Nathan Lucas Nuzum, Quasqueton, IA (US)

(21) Appl. No.: 17/649,862

(22) Filed: Feb. 3, 2022

Related U.S. Application Data
(60) Provisional application No. 63/200,020, filed on Feb. 10, 2021.

(51) Int. Cl. H03F 1/02; H03F 3/24; H03F 3/60

(52) U.S. Cl. CPC H03F 1/0288; H03F 2200/451; H03F 3/602; H03F 3/245

(57) ABSTRACT

Load modulated Doherty power amplifiers are provided herein. In certain embodiments, a load modulated Doherty power amplifier includes a combiner, a carrier amplifier having an output coupled to a first terminal of the combiner, a peaking amplifier having an output coupled to a second terminal of the combiner, a load modulating amplifier having an output coupled to a third terminal of the combiner, and a radio frequency (RF) output port that is coupled to a fourth terminal of the combiner and provides an RF output signal. The peaking amplifier is operable to activate at a first power threshold, while the load modulating amplifier is operable to activate at a second power threshold to modulate down a load of the carrier amplifier and of the peaking amplifier.

### CROSS-REFERENCE TO RELATED APPLICATIONS

This application claims the benefit of priority under 35 U.S.C. § 119 of U.S. Provisional Patent Application No. 63/200,020, filed Feb. 10, 2021 and titled “LOAD MODULATED DOHERTY POWER AMPLIFIERS,” which is herein incorporated by reference in its entirety.

### BACKGROUND

### Field

Embodiments of the invention relate to electronic systems, and in particular, to radio frequency (RF) electronics.

### Description of the Related Technology

Power amplifiers are used in RF communication systems to amplify RF signals for transmission via antennas.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 425 MHz to about 7.125 GHz for Frequency Range 1 (FR1) of the Fifth Generation (5G) communication standard or in the range of about 24.250 GHz to about 52.600 GHz for Frequency Range 2 (FR2) of the 5G communication standard.

### SUMMARY

In certain embodiments, the present disclosure relates to a power amplifier system. The power amplifier system includes a combiner including a first terminal, a second terminal, a third terminal, and a fourth terminal, the combiner configured to provide a radio frequency output signal from the fourth terminal. The power amplifier system further includes a carrier amplifier including an output coupled to the first terminal of the combiner, a peaking amplifier including an output coupled to the second terminal of the combiner, and a load modulating amplifier including an output coupled to the third terminal of the combiner.

In some embodiments, the peaking amplifier is configured to activate at a first power threshold, and the load modulating amplifier is configured to activate at a second power threshold greater than the first power threshold. According to various embodiments, when activated the load modulating power amplifier is operable to modulate down a load of the carrier amplifier and of the peaking amplifier. In accordance with several embodiments, the carrier amplifier includes a saturation detector configured to monitor an amount of saturation of the carrier amplifier, the saturation detector operable to control activation of the peaking amplifier and to control activation of the load modulating amplifier. According to a number of embodiments, the carrier amplifier includes a class AB bias circuit, the peaking amplifier includes a first class C bias circuit, and the load modulating amplifier includes a second class C bias circuit.

In various embodiments, the load modulating amplifier includes a cascode amplifier stage. According to a number of embodiments, the carrier amplifier includes a first common-emitter amplifier stage, and the peaking amplifier includes a second common-emitter amplifier stage.

In several embodiments, the combiner is a hybrid coupler, the first terminal corresponding to a zero degree port, the second terminal corresponding to a ninety degree port, the third terminal corresponding to an isolation port, and the fourth terminal corresponding to a common port.

In some embodiments, the power amplifier system further includes an input splitter configured to split a radio frequency input signal into a plurality of input signal components including a first input signal component provided to an input of the carrier amplifier and a second input signal component provided to an input of the peaking amplifier. According to a number of embodiments, the plurality of input signal components further include a third input signal component provided to an input of the load modulating amplifier.

In certain embodiments, the present disclosure relates to a mobile device. The mobile device includes an antenna configured to transmit a radio frequency output signal, and a front end system. The front end system includes a power amplifier system including a combiner, a carrier amplifier having an output coupled to a first terminal of the combiner, a peaking amplifier having an output coupled to a second terminal of the combiner, and a load modulating amplifier having an output coupled to a third terminal of the combiner, the combiner configured to provide the radio frequency output signal at a fourth terminal.

In various embodiments, the peaking amplifier is configured to activate at a first power threshold, and the load modulating amplifier is configured to activate at a second power threshold greater than the first power threshold. According to several embodiments, when activated the load modulating power amplifier is operable to modulate down a load of the carrier amplifier and of the peaking amplifier. In accordance with some embodiments, the carrier amplifier includes a saturation detector configured to monitor an amount of saturation of the carrier amplifier, the saturation detector operable to control activation of the peaking amplifier and to control activation of the load modulating amplifier. According to a number of embodiments, the carrier amplifier includes a class AB bias circuit, the peaking amplifier includes a first class C bias circuit, and the load modulating amplifier includes a second class C bias circuit.

In various embodiments, the load modulating amplifier includes a cascode amplifier stage. According to several embodiments, the carrier amplifier includes a first common-emitter amplifier stage, and the peaking amplifier includes a second common-emitter amplifier stage.

In a number of embodiments, the combiner is a hybrid coupler, the first terminal corresponding to a zero degree port, the second terminal corresponding to a ninety degree port, the third terminal corresponding to an isolation port, and the fourth terminal corresponding to a common port.

In several embodiments, the mobile device includes an input splitter configured to split a radio frequency input signal into a plurality of input signal components including a first input signal component provided to an input of the carrier amplifier and a second input signal component provided to an input of the peaking amplifier. According to a number of embodiments, the plurality of input signal components further include a third input signal component provided to an input of the load modulating amplifier.

In certain embodiments, the present disclosure relates to a method of amplification in a mobile phone. The method includes providing a first radio frequency signal from an output of a carrier amplifier to a first terminal of a combiner, providing a first radio frequency signal from an output of a peaking amplifier to a second terminal of the combiner, providing a first radio frequency signal from an output of a load modulating amplifier to a third terminal of the combiner, and combining the first radio frequency signal, the second radio frequency signal, and the third radio frequency signal to generate a radio frequency output signal using the combiner, and providing the radio frequency output signal at a fourth terminal of the combiner.

In various embodiments, the method further includes activating the peaking amplifier at a first power threshold, and activating the load modulating amplifier at a second power threshold greater than the first power threshold. According to a number of embodiments, activating the load modulating amplifier includes modulating down a load of the carrier amplifier and of the peaking amplifier.

### BRIEF DESCRIPTION OF THE DRAWINGS

Embodiments of this disclosure will now be described, by way of non-limiting example, with reference to the accompanying drawings.

FIG. 1 is a schematic diagram of one embodiment of a load modulated Doherty power amplifier.

FIG. 2 is a schematic diagram of another embodiment of a load modulated Doherty power amplifier.

FIG. 3 is a schematic diagram of another embodiment of a load modulated Doherty power amplifier.

FIG. 4 is a schematic diagram of another embodiment of a load modulated Doherty power amplifier.

FIG. 5 is a schematic diagram of another embodiment of a load modulated Doherty power amplifier.

FIG. 6 is a schematic diagram of another embodiment of a load modulated Doherty power amplifier.

FIG. 7 is a graph of one example of gain versus output power for a load modulated Doherty power amplifier.

FIG. 8 is a graph of one example of power added efficiency (PAE) versus output power for a load modulated Doherty power amplifier.

FIG. 9 is a graph of another example of PAE versus output power for a load modulated Doherty power amplifier.

FIG. 10 is a schematic diagram of one embodiment of a mobile device.

FIG. 11 is a schematic diagram of a power amplifier system according to another embodiment.

FIG. 12A is a schematic diagram of one embodiment of a packaged module.

FIG. 12B is a schematic diagram of a cross-section of the packaged module of FIG. 12A taken along the lines 12B-12B.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The linearity of a power amplifier is directly related to a level of gain compression within the power amplifier. Thus, a power amplifier can be designed for a fixed supply voltage that defines the target load impedance for acceptable linearity.

In certain applications, such as mobile handsets, operating environment leads to a relatively large variation in the load presented to a power amplifier. For example, a voltage standing wave ratio (VSWR) of an antenna and thus the power amplifier's load can vary based on a user's handling of the mobile handset. The load variation degrades power amplifier linearity and/or spectral performance.

One type of power amplifier is a Doherty power amplifier, which includes a main or carrier amplifier and an auxiliary or peaking amplifier that operate in combination with one another to amplify an RF signal. The Doherty power amplifier combines a carrier signal from the carrier amplifier and a peaking signal from the peaking amplifier to generate an amplified RF output signal. In certain implementations, the carrier amplifier is enabled over a wide range of power levels (for instance, by a class AB bias circuit) while the peaking amplifier is selectively enabled (for instance, by a class C bias circuit) at high power levels.

Such Doherty power amplifiers operate with high efficiency at 6dB power back-off, but suffer from inefficiencies at lower power levels, for very high peak-to-average ratio (PAPR) waveforms, and/or when the output power is not well-centered at the peak of the amplifier's power-dependent efficiency profile. For example, advanced modulation schemes with high PAPR (for instance, 5G waveforms) require the amplifier to be operated several dB from the maximum saturated output power (Psat) to maintain linearity.

Moreover, the linearity of a Doherty power amplifier is particularly susceptible to degradation in the presence of load variation. For example, an amplitude distortion (AM/AM) of the carrier amplifier is a function of load VSWR, while the AM/AM of the peaking amplifier is a function of input power, which is typically uncorrelated to the load VSWR.

Load modulated Doherty power amplifiers are provided herein. In certain embodiments, a load modulated Doherty power amplifier includes a combiner, a carrier amplifier having an output coupled to a first terminal of the combiner, a peaking amplifier having an output coupled to a second terminal of the combiner, a load modulating amplifier having an output coupled to a third terminal of the combiner, and an RF output port that is coupled to a fourth terminal of the combiner and provides an RF output signal. The peaking amplifier is operable to activate at a first power threshold, while the load modulating amplifier is operable to activate at a second power threshold to modulate down a load of the carrier amplifier and of the peaking amplifier.

For example, in one implementation, only the carrier amplifier is activated up to about 24 dBm of input signal power. Additionally, from about 24 dBm to 30 dBm of input signal power both the carrier amplifier and the peaking amplifier are activated and operate in a Doherty mode (as a Doherty amplifier). Furthermore, above about 30 dBm of input signal power the load modulating amplifier is activated and the load to the Doherty amplifier is reduced such that output power is increased.

Such a load modulated Doherty power amplifier can operate with extremely high power added efficiency (PAE) over a wide dynamic range. In one example, over 58% rated PAE is achieved over 9 dB of dynamic range.

In addition to providing high PAE over a wide dynamic range, load modulated Doherty power amplifiers exhibit a number of other advantages including, but not limited to, robust phase performance of the peaking amplifier, an ability to separately control harmonic termination of the carrier amplifier and the peaking amplifier, and/or excellent power amplification characteristics for a wide range of signal types and frequency ranges.

In certain implementations, the combiner is implemented as a 3 dB hybrid coupler. Additionally, the output impedance of the load modulating amplifier can be scaled to be about −jX, where X is the characteristic impedance of the coupler. Before the load modulating amplifier turns on, the power amplifier operates in a manner similar to a Doherty amplifier. However, once the Doherty amplifier has about equal power contribution from the carrier amplifier path and the peaking amplifier path, the load modulating amplifier turns on and modulates the load of the Doherty power amplifier to a lower impedance to achieve higher output power (for instance, about 5 dB higher power).

Load modulated Doherty power amplifiers can be included in a wide variety of RF communication systems, including, but not limited to, base stations, network access points, mobile phones, tablets, customer-premises equipment (CPE), laptops, computers, wearable electronics, and/or other communication devices.

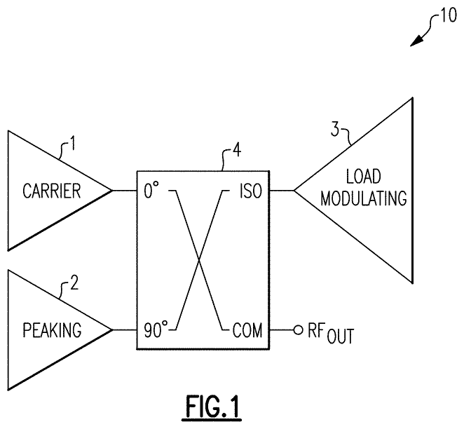

FIG. 1 is a schematic diagram of one embodiment of a load modulated Doherty power amplifier 10. The load modulated Doherty power amplifier 10 includes a carrier amplifier 1, a peaking amplifier 2, a load modulating amplifier 3, and a combiner 4 (implemented as a 3 dB hybrid coupler, in this embodiment).

In the illustrated embodiment, the combiner 4 includes a first terminal (a thru port or 0° port, in this example), a second terminal (a coupling port or 90° port, in this example), a third terminal (an isolation port or ISO port, in this example), and a fourth terminal (a common port or COM port, in this example). As shown in FIG. 1, the 0° port is connected to an output of the carrier amplifier 1, the 90° port is coupled to an output of the peaking amplifier 2, the ISO port is coupled to an output of the load modulating amplifier 3, and the COM port is coupled to an RF output RF_{OUT} of the load modulated Doherty power amplifier 10.

The carrier amplifier 1 and the peaking amplifier 2 operate to amplify components of an RF input signal. The components of the RF input signal amplified by the carrier amplifier 1 and the peaking amplifier 2 can have a phase difference or delay. For example, in certain implementations, an input splitter (for example, another 3 dB hybrid coupler) outputs a pair of RF input signal components having a separation of about 90 degrees, and the pair of RF input signal components are amplified by the carrier amplifier 1 and the peaking amplifier 2. In certain implementations, the load modulating amplifier 3 also receives a signal component of the RF input signal.

With continuing reference to FIG. 1, the peaking amplifier 2 is operable to activate at a first power threshold, while the load modulating amplifier 3 is operable to activate at a second power threshold to modulate down a load of the carrier amplifier 1 and the peaking amplifier 2. The second power threshold is greater than the first power threshold.

For example, in one implementation, only the carrier amplifier 1 is activated up to about 24 dBm of input signal power. Additionally, from about 24 dBm to 30 dBm of input signal power both the carrier amplifier 1 and the peaking amplifier 2 are activated and operate in a Doherty mode (as a Doherty amplifier). Furthermore, above about 30 dBm of input signal power the load modulating amplifier 3 is activated and the load to the Doherty amplifier is reduced such that output power is increased.

The combiner 4 operates to combine the amplified RF input signal components to generate an amplified RF output signal that is provided on the RF output RF_{OUT}.

The load modulated Doherty power amplifier 10 provides a number of advantages including, but not limited to, high PAE over wide dynamic range. In one example, over 58% rated PAE is achieved over 9 dB of dynamic range. Thus, the load modulated Doherty power amplifier 10 is well-suited for amplifying complex waveforms with high PAPR, for instance, 5G waveforms.

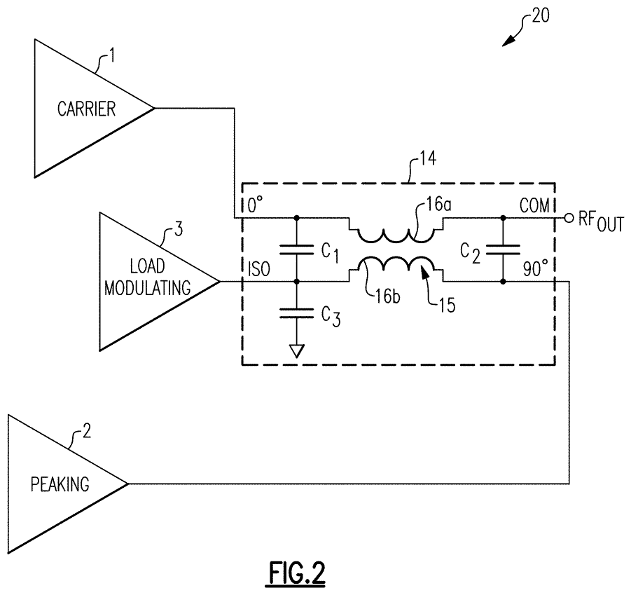

FIG. 2 is a schematic diagram of another embodiment of a load modulated Doherty power amplifier 20. The load modulated Doherty power amplifier 20 includes a carrier amplifier 1, a peaking amplifier 2, a load modulating amplifier 3, and a 3 dB hybrid coupler 14.

The load modulated Doherty power amplifier 20 of FIG. 2 is similar to the load modulated Doherty power amplifier 10 of FIG. 1, except that the load modulated Doherty power amplifier 20 illustrates one specific implementation of a combiner.

In particular, the 3 dB hybrid coupler 14 of FIG. 2 includes a first winding 16a and a second winding 16b that are electromagnetically coupled to one another. Additionally, the first winding 16a is connected between a 0° port and a COM port, while the second winding 16b is connected between an ISO port and a 90° port. The 3 dB hybrid coupler 14 further includes a first capacitor C₁ connected between the 0° port and the ISO port, a second capacitor C₂ connected between the COM port and the 90° port, and a third capacitor C₃ connected between the ISO port and a ground voltage (ground).

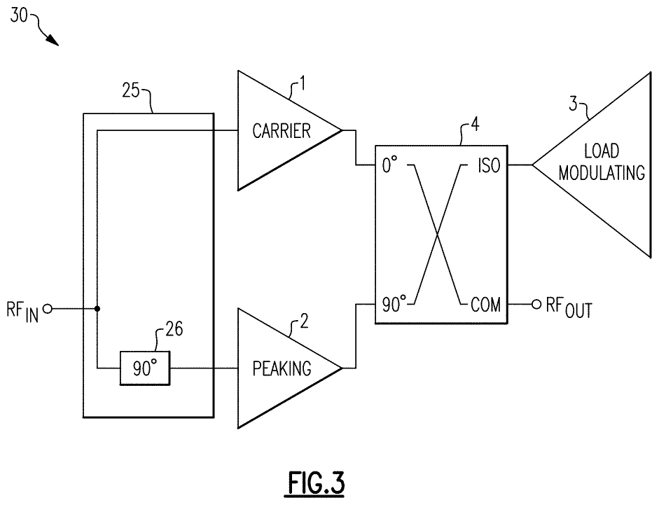

FIG. 3 is a schematic diagram of another embodiment of a load modulated Doherty power amplifier 30. The load modulated Doherty power amplifier 30 includes a carrier amplifier 1, a peaking amplifier 2, a load modulating amplifier 3, combiner 4, and an input splitter 25.

The load modulated Doherty power amplifier 30 of FIG. 3 is similar to the load modulated Doherty power amplifier 10 of FIG. 1, except that the load modulated Doherty power amplifier 30 further includes an input splitter 25 operable to split an RF input signal received from an RF input RF_{IN} into a first RF input signal component amplified by the carrier amplifier 1 and a second RF input signal component amplified by the peaking amplifier 2. In this example, the input splitter 25 includes a phase shifter 26 for delaying the second RF input signal component by about 90° relative to the first RF input signal. Although not depicted in FIG. 3, in certain implementations the RF input splitter 25 further generates a third RF input signal component for the load modulating amplifier 3.

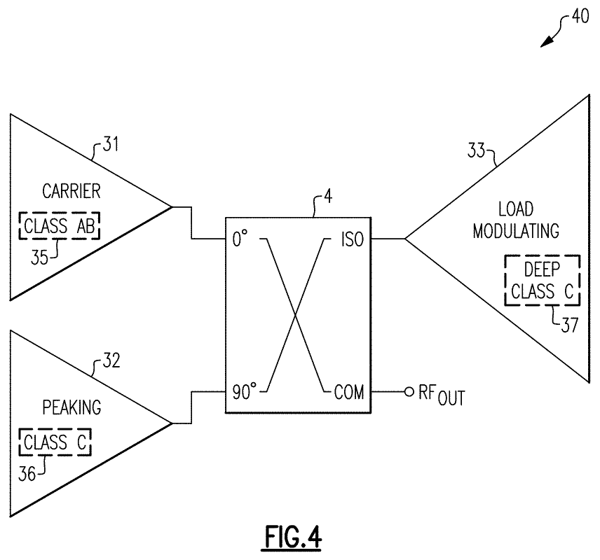

FIG. 4 is a schematic diagram of another embodiment of a load modulated Doherty power amplifier 40. The load modulated Doherty power amplifier 40 includes a carrier amplifier 31, a peaking amplifier 32, a load modulating amplifier 33, and combiner 4.

The load modulated Doherty power amplifier 40 of FIG. 4 is similar to the load modulated Doherty power amplifier 10 of FIG. 1, except that the load modulated Doherty power amplifier 40 illustrates specific implementations of amplifier biasing.

In particular, in the embodiment of FIG. 4, the carrier amplifier 31 includes a class AB biasing circuit 35, the peaking amplifier 32 includes a class C bias circuit 36, and the load modulating amplifier 33 includes a deep class C bias circuit 37 that activates at a higher power threshold relative to the class C bias circuit 36. Although one embodiment of biasing a load modulated Doherty power amplifier is shown, the teachings herein are applicable to other implementations of biasing.

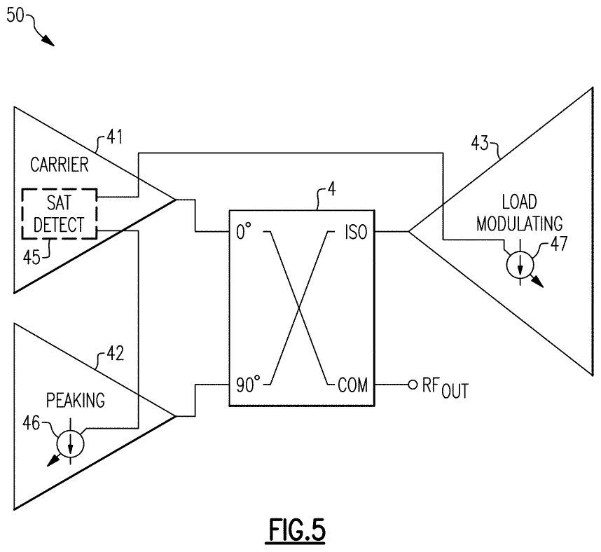

FIG. 5 is a schematic diagram of another embodiment of a load modulated Doherty power amplifier 50. The load modulated Doherty power amplifier 50 includes a carrier amplifier 41, a peaking amplifier 42, a load modulating amplifier 43, and combiner 4.

The load modulated Doherty power amplifier 50 of FIG. 5 is similar to the load modulated Doherty power amplifier 10 of FIG. 1, except that the load modulated Doherty power amplifier 50 illustrates specific implementations of amplifier biasing.

In particular, the carrier amplifier 41 includes a saturation detector 45 that saturation of the carrier amplifier 41. Additionally, the peaking amplifier 42 includes a first controllable bias current source 46 that is controlled by a first control signal from the saturation detector 45, while the load modulating amplifier 43 includes a second controllable bias current source 47 that is controlled by a second control signal from the saturation detector 45.

As the carrier amplifier 41 begins to saturate, the saturation detector 45 uses the first control signal to control the first controllable bias current source 46 to activate the peaking amplifier 42. Additionally, as the carrier amplifier 41 when the saturation of the carrier amplifier 41 is even deeper, the saturation detector 45 uses the second control signal to control the second controllable bias current source 47 to activate the load modulating amplifier 43. Accordingly, in this embodiment the saturation detector 45 is used to set the first power threshold for activating the peaking amplifier 42 and the second power threshold for activating the load modulating amplifier 43.

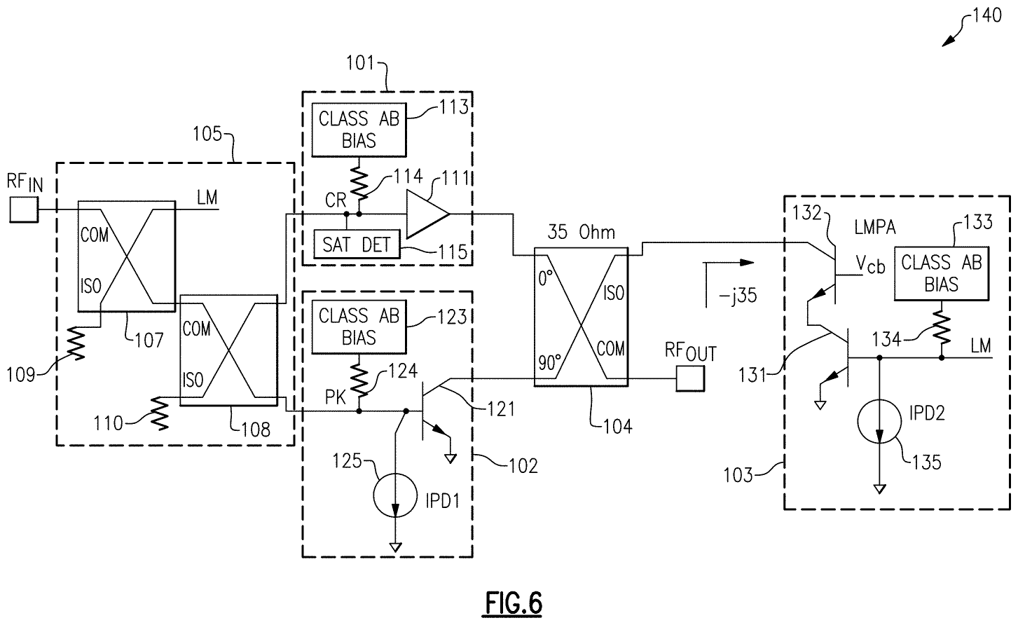

FIG. 6 is a schematic diagram of another embodiment of a load modulated Doherty power amplifier 140. The load modulated Doherty power amplifier 140 includes a carrier amplifier 101, a peaking amplifier 102, a load modulating amplifier 103, a 3 dB hybrid coupler 104, and an input splitter 105.

In the illustrated embodiment, the input splitter 105 includes a first 3 dB hybrid coupler 107, a second 3 dB hybrid coupler 108, a first termination resistor 109, and a second termination resistor 110. A COM port of the first 3 dB hybrid coupler 107 is coupled to the RF input RF_{IN}, while an ISO port of the first 3 dB hybrid coupler 107 is connected to the first termination resistor 109 (which can be connected to ground, in certain implementations). Additionally, a 90° port of the first 3 dB hybrid coupler 107 outputs an input signal component LM for the load modulating amplifier 103, while a 0° port of the first 3 dB hybrid coupler 107 is connected to a COM port of the second 3 dB hybrid coupler 108. Additionally, an ISO port of the second 3 dB hybrid coupler 108 is connected to the second termination resistor 110 (which can be connected to ground, in certain implementations), while a 90° port of the second 3 dB hybrid coupler 108 outputs an input signal component CR for the carrier amplifier 101 and a 0° port of the second 3 dB hybrid coupler 108 outputs an input signal component PK for the peaking amplifier 102.

The carrier amplifier 101 includes a carrier amplification stage 111 (for instance, a common-emitter amplifier stage or other suitable stage), a class AB bias circuit 113, a bias resistor 114, and a saturation detector 115. The carrier amplifier 101 includes an input that receives the input signal component CR and an output coupled to a 0° port of the 3 dB hybrid coupler 104. The class AB bias circuit 113 biases the carrier amplification stage 111, while the saturation detector 115 detects for an amount of saturation of the carrier amplification stage 111.

With continuing reference to FIG. 6, the peaking amplifier 102 includes a common-emitter amplifier stage 121, a class AB bias circuit 123, a bias resistor 124, and a controllable current source 125 controlled by the saturation detector 115 of the carrier amplifier 101. The peaking amplifier 102 includes an input that receives the input signal component PK, and an output coupled to a 90° port of the 3 dB hybrid coupler 104.

The load modulating amplifier 103 includes a cascode amplifier stage implemented using a gain transistor 131 and a cascode transistor 132. The load modulating amplifier 103 further includes a class AB bias circuit 133, a bias resistor 134, and a controllable current source 135 controlled by the saturation detector 115 of the carrier amplifier 101. The load modulating amplifier 103 includes an input that receives the input signal component LM, and an output coupled to an ISO port of the 3 dB hybrid coupler 104.

In the illustrated embodiment, the 3 dB hybrid coupler 104 further includes a COM port connected to the RF output RF_{OUT}. In this embodiment, the 3 dB hybrid coupler 104 has a characteristic impedance of X, and the output impedance of the load modulating amplifier 103 is about −jX. In one example, X is about 35 Ohms.

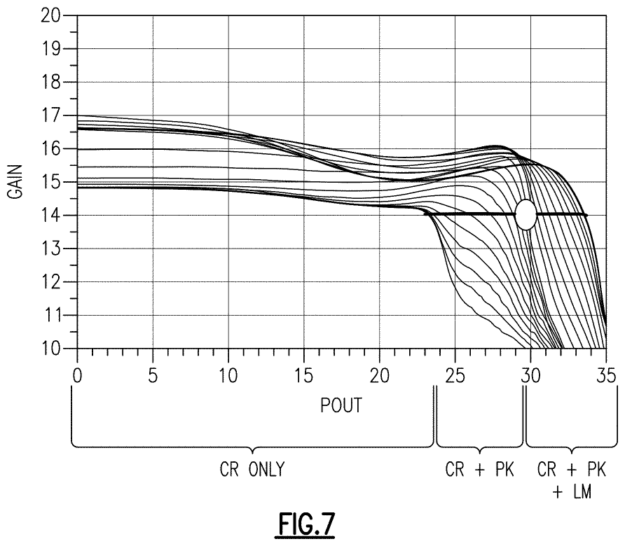

FIG. 7 is a graph of one example of gain versus output power for a load modulated Doherty power amplifier. The graph includes gain versus output power plots for different bias current conditions for one implementation of the load modulated Doherty power amplifier 140 of FIG. 6.

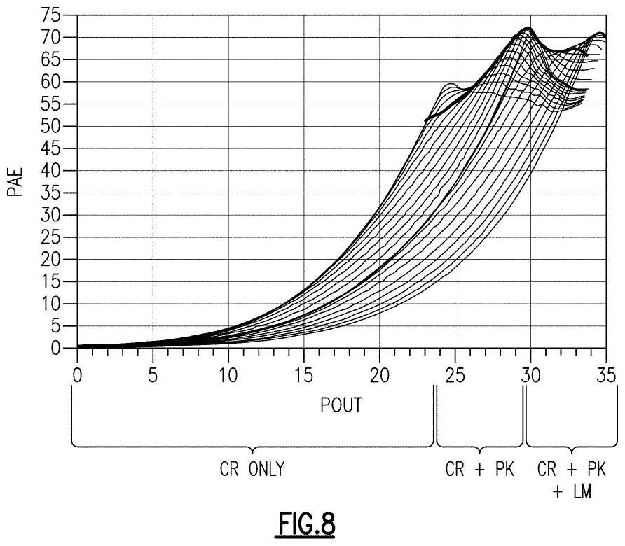

FIG. 8 is a graph of one example of power added efficiency (PAE) versus output power for a load modulated Doherty power amplifier. The graph includes PAE versus output power plots for different bias current conditions for one implementation of the load modulated Doherty power amplifier 140 of FIG. 6.

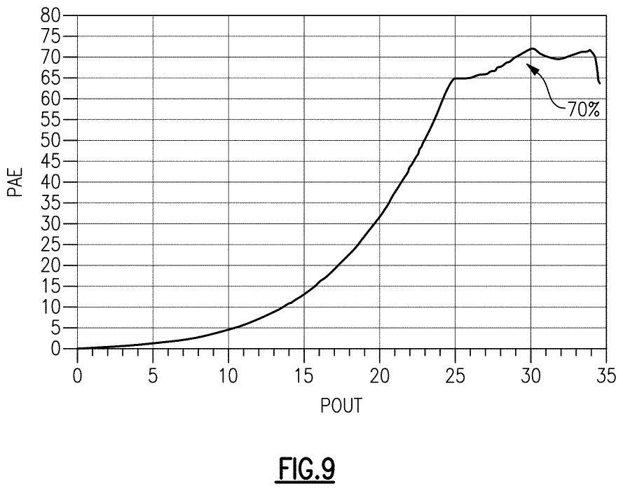

FIG. 9 is a graph of another example of PAE versus output power for a load modulated Doherty power amplifier. The graph depicts PAE performance for one implementation of the load modulated Doherty power amplifier 140 of FIG. 6. In this example, 70% PAE at 5 dB power-back off (PBO) is achieved.

Although FIGS. 7-9 depict one example of performance results for a load modulated Doherty power amplifier, other performance results are possible. For example, performance results of a load modulated Doherty power amplifier can depend on a variety of factors including, but not limited to, amplifier implementation, operating conditions, frequency range, and/or simulation/measurement environment.

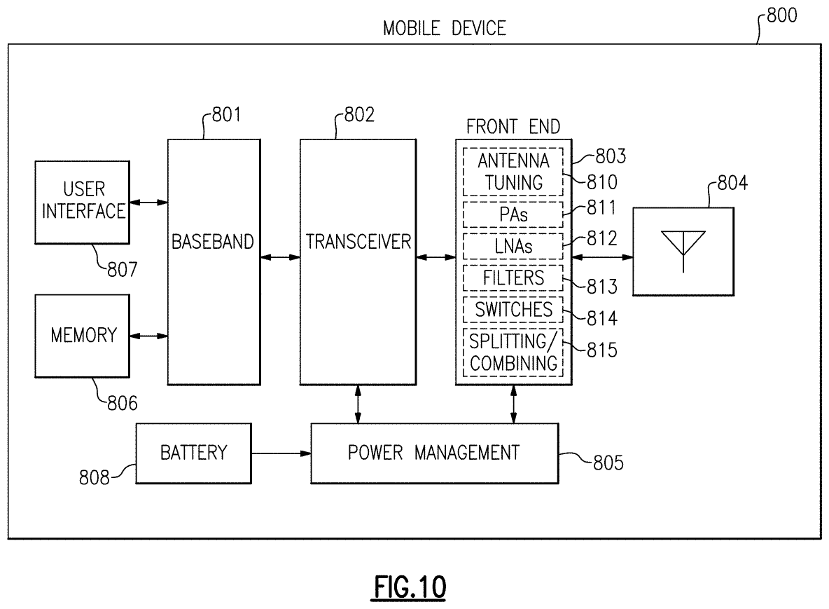

FIG. 10 is a schematic diagram of one embodiment of a mobile device 800. The mobile device 800 includes a baseband system 801, a transceiver 802, a front end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 10 as the transceiver 802. In one example, separate components (for instance, separate circuits or dies) can be provided for handling certain types of RF signals.

The front end system 803 aids in conditioning signals transmitted to and/or received from the antennas 804. In the illustrated embodiment, the front end system 803 includes antenna tuning circuitry 810, power amplifiers (PAs) 811, low noise amplifiers (LNAs) 812, filters 813, switches 814, and signal splitting/combining circuitry 815. However, other implementations are possible.

For example, the front end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

At least one of the power amplifiers 811 is implemented as a load modulated Doherty power amplifier in accordance with the teachings herein. Although the mobile device 800 illustrates one embodiment of a communication system that can be implemented with one or more load modulated Doherty power amplifiers, the teachings herein are applicable to a wide range of systems. Accordingly, other implementations are possible.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 10, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 10, the power management system 805 receives a battery voltage from the battery 808. The battery 808 can be any suitable battery for use in the mobile device 800, including, for example, a lithium-ion battery.

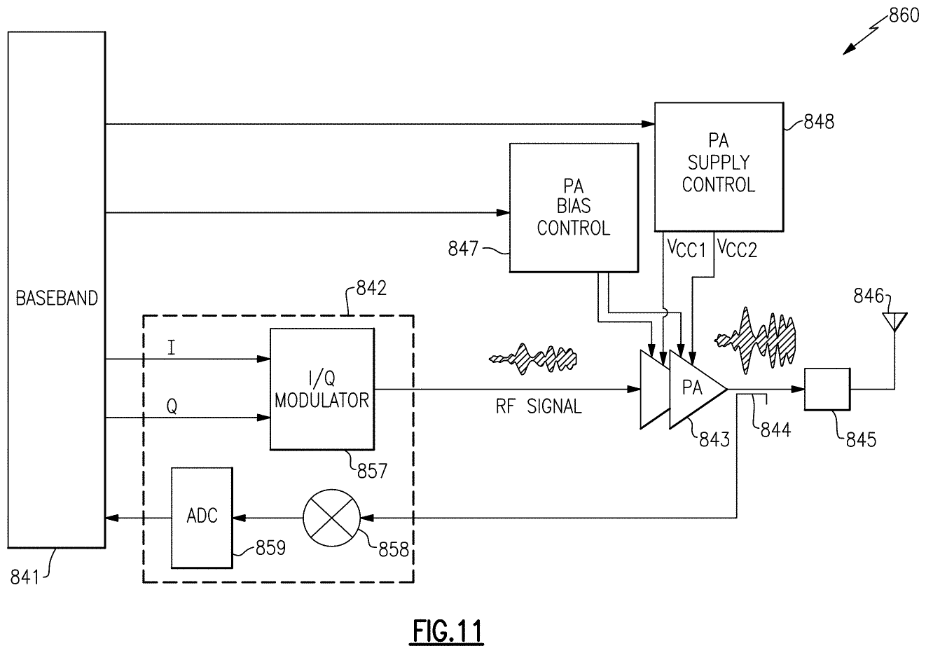

FIG. 11 is a schematic diagram of a power amplifier system 860 according to another embodiment. The illustrated power amplifier system 860 includes a baseband processor 841, a transmitter/observation receiver 842, a power amplifier (PA) 843, a directional coupler 844, front-end circuitry 845, an antenna 846, a PA bias control circuit 847, and a PA supply control circuit 848. The illustrated transmitter/observation receiver 842 includes an I/Q modulator 857, a mixer 858, and an analog-to-digital converter (ADC) 859. In certain implementations, the transmitter/observation receiver 842 is incorporated into a transceiver.

The baseband processor 841 can be used to generate an in-phase (I) signal and a quadrature-phase (Q) signal, which can be used to represent a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals can be provided to the I/Q modulator 857 in a digital format. The baseband processor 841 can be any suitable processor configured to process a baseband signal. For instance, the baseband processor 841 can include a digital signal processor, a microprocessor, a programmable core, or any combination thereof. Moreover, in some implementations, two or more baseband processors 821 can be included in the power amplifier system 860.

The I/Q modulator 857 can be configured to receive the I and Q signals from the baseband processor 821 and to process the I and Q signals to generate an RF signal. For example, the I/Q modulator 857 can include digital-to-analog converters (DACs) configured to convert the I and Q signals into an analog format, mixers for upconverting the I and Q signals to RF, and a signal combiner for combining the upconverted I and Q signals into an RF signal suitable for amplification by the power amplifier 843. In certain implementations, the I/Q modulator 857 can include one or more filters configured to filter frequency content of signals processed therein.

The power amplifier 843 can receive the RF signal from the I/Q modulator 857, and when enabled can provide an amplified RF signal to the antenna 846 via the front-end circuitry 845. The power amplifier 843 can be implemented in accordance with any of the load modulating schemes herein.

The front-end circuitry 845 can be implemented in a wide variety of ways. In one example, the front-end circuitry 845 includes one or more switches, filters, duplexers, multiplexers, and/or other components. In another example, the front-end circuitry 845 is omitted in favor of the power amplifier 843 providing the amplified RF signal directly to the antenna 846.

The directional coupler 844 senses an output signal of the power amplifier 823. Additionally, the sensed output signal from the directional coupler 844 is provided to the mixer 858, which multiplies the sensed output signal by a reference signal of a controlled frequency. The mixer 858 operates to generate a downshifted signal by downshifting the sensed output signal's frequency content. The downshifted signal can be provided to the ADC 859, which can convert the downshifted signal to a digital format suitable for processing by the baseband processor 841. Including a feedback path from the output of the power amplifier 843 to the baseband processor 841 can provide a number of advantages. For example, implementing the baseband processor 841 in this manner can aid in providing power control, compensating for transmitter impairments, and/or in performing digital pre-distortion (DPD). Although one example of a sensing path for a power amplifier is shown, other implementations are possible.

The PA supply control circuit 848 receives a power control signal from the baseband processor 841, and controls supply voltages of the power amplifier 843. In the illustrated configuration, the PA supply control circuit 848 generates a first supply voltage V_{CC1} for powering an input stage of the power amplifier 843 and a second supply voltage V_{CC2} for powering an output stage of the power amplifier 843. The PA supply control circuit 848 can control the voltage level of the first supply voltage V_{CC1} and/or the second supply voltage V_{CC2} to enhance the power amplifier system's PAE.

The PA supply control circuit 848 can employ various power management techniques to change the voltage level of one or more of the supply voltages over time to improve the power amplifier's power added efficiency (PAE), thereby reducing power dissipation.

One technique for improving efficiency of a power amplifier is average power tracking (APT), in which a DC-to-DC converter is used to generate a supply voltage for a power amplifier based on the power amplifier's average output power. Another technique for improving efficiency of a power amplifier is envelope tracking (ET), in which a supply voltage of the power amplifier is controlled in relation to the envelope of the RF signal. Thus, when a voltage level of the envelope of the RF signal increases the voltage level of the power amplifier's supply voltage can be increased. Likewise, when the voltage level of the envelope of the RF signal decreases the voltage level of the power amplifier's supply voltage can be decreased to reduce power consumption.

In certain configurations, the PA supply control circuit 848 is a multi-mode supply control circuit that can operate in multiple supply control modes including an APT mode and an ET mode. For example, the power control signal from the baseband processor 841 can instruct the PA supply control circuit 848 to operate in a particular supply control mode.

As shown in FIG. 11, the PA bias control circuit 847 receives a bias control signal from the baseband processor 841, and generates bias control signals for the power amplifier 843. In the illustrated configuration, the bias control circuit 847 generates bias control signals for both an input stage of the power amplifier 843 and an output stage of the power amplifier 843. However, other implementations are possible.

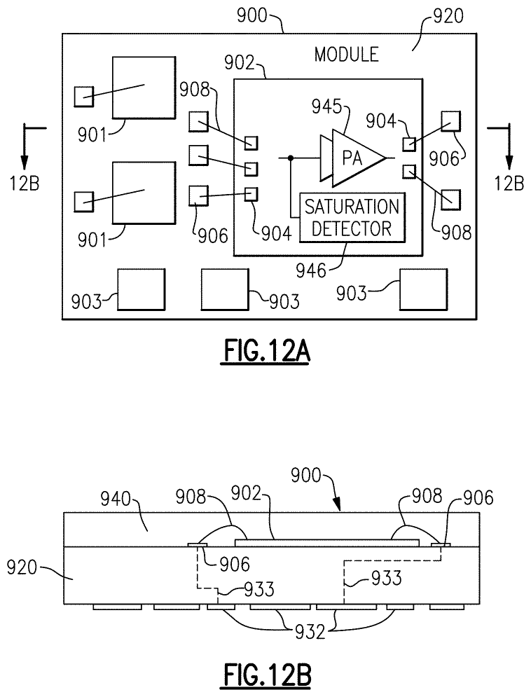

FIG. 12A is a schematic diagram of one embodiment of a packaged module 900. FIG. 12B is a schematic diagram of a cross-section of the packaged module 900 of FIG. 12A taken along the lines 12B-12B.

The packaged module 900 includes radio frequency components 901, a semiconductor die 902, surface mount devices 903, wirebonds 908, a package substrate 920, and an encapsulation structure 940. The package substrate 920 includes pads 906 formed from conductors disposed therein. Additionally, the semiconductor die 902 includes pins or pads 904, and the wirebonds 908 have been used to connect the pads 904 of the die 902 to the pads 906 of the package substrate 920.

The semiconductor die 902 includes a load modulated Doherty power amplifier 945, which can be implemented in accordance with any of the embodiments herein. In this embodiment, a saturation detector 946 is also included for controlling activation of the peaking and load modulating amplifiers. However, other implementations of biasing/activation control are possible.

The packaging substrate 920 can be configured to receive a plurality of components such as radio frequency components 901, the semiconductor die 902 and the surface mount devices 903, which can include, for example, surface mount capacitors and/or inductors. In one implementation, the radio frequency components 901 include integrated passive devices (IPDs).

As shown in FIG. 12B, the packaged module 900 is shown to include a plurality of contact pads 932 disposed on the side of the packaged module 900 opposite the side used to mount the semiconductor die 902. Configuring the packaged module 900 in this manner can aid in connecting the packaged module 900 to a circuit board, such as a phone board of a mobile device. The example contact pads 932 can be configured to provide radio frequency signals, bias signals, and/or power (for example, a power supply voltage and ground) to the semiconductor die 902 and/or other components. As shown in FIG. 12B, the electrical connections between the contact pads 932 and the semiconductor die 902 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A power amplifier system comprising:
a combiner including a first terminal, a second terminal, a third terminal, and a fourth terminal, the combiner configured to provide a radio frequency output signal from the fourth terminal;
a carrier amplifier including an output coupled to the first terminal of the combiner;
a peaking amplifier including an output coupled to the second terminal of the combiner; and
a load modulating amplifier including an output coupled to the third terminal of the combiner.

2. The power amplifier system of claim 1 wherein the peaking amplifier is configured to activate at a first power threshold, and the load modulating amplifier is configured to activate at a second power threshold greater than the first power threshold.

3. The power amplifier system of claim 2 wherein when activated the load modulating power amplifier is operable to modulate down a load of the carrier amplifier and of the peaking amplifier.

4. The power amplifier system of claim 2 wherein the carrier amplifier includes a saturation detector configured to monitor an amount of saturation of the carrier amplifier, the saturation detector operable to control activation of the peaking amplifier and to control activation of the load modulating amplifier.

5. The power amplifier system of claim 2 wherein the carrier amplifier includes a class AB bias circuit, the peaking amplifier includes a first class C bias circuit, and the load modulating amplifier includes a second class C bias circuit.

6. The power amplifier system of claim 1 wherein the load modulating amplifier includes a cascode amplifier stage.

7. The power amplifier system of claim 6 wherein the carrier amplifier includes a first common-emitter amplifier stage, and the peaking amplifier includes a second common-emitter amplifier stage.

8. The power amplifier system of claim 1 wherein the combiner is a hybrid coupler, the first terminal corresponding to a zero degree port, the second terminal corresponding to a ninety degree port, the third terminal corresponding to an isolation port, and the fourth terminal corresponding to a common port.

9. The power amplifier system of claim 1 further comprising an input splitter configured to split a radio frequency input signal into a plurality of input signal components including a first input signal component provided to an input of the carrier amplifier and a second input signal component provided to an input of the peaking amplifier.

10. The power amplifier system of claim 9 wherein the plurality of input signal components further include a third input signal component provided to an input of the load modulating amplifier.

11. A mobile device comprising:
an antenna configured to transmit a radio frequency output signal; and
a front end system including a power amplifier system including a combiner, a carrier amplifier having an output coupled to a first terminal of the combiner, a peaking amplifier having an output coupled to a second terminal of the combiner, and a load modulating amplifier having an output coupled to a third terminal of the combiner, the combiner configured to provide the radio frequency output signal at a fourth terminal.

12. The mobile device of claim 11 wherein the peaking amplifier is configured to activate at a first power threshold, and the load modulating amplifier is configured to activate at a second power threshold greater than the first power threshold.

13. The mobile device of claim 12 wherein when activated the load modulating power amplifier is operable to modulate down a load of the carrier amplifier and of the peaking amplifier.

14. The mobile device of claim 12 wherein the carrier amplifier includes a saturation detector configured to monitor an amount of saturation of the carrier amplifier, the saturation detector operable to control activation of the peaking amplifier and to control activation of the load modulating amplifier.

15. The mobile device of claim 12 wherein the carrier amplifier includes a class AB bias circuit, the peaking amplifier includes a first class C bias circuit, and the load modulating amplifier includes a second class C bias circuit.

16. The mobile device of claim 11 wherein the load modulating amplifier includes a cascode amplifier stage.

17. The mobile device of claim 11 wherein the combiner is a hybrid coupler, the first terminal corresponding to a zero degree port, the second terminal corresponding to a ninety degree port, the third terminal corresponding to an isolation port, and the fourth terminal corresponding to a common port.

18. A method of amplification in a mobile phone, the method comprising:
providing a first radio frequency signal from an output of a carrier amplifier to a first terminal of a combiner;
providing a first radio frequency signal from an output of a peaking amplifier to a second terminal of the combiner;
providing a first radio frequency signal from an output of a load modulating amplifier to a third terminal of the combiner; and
combining the first radio frequency signal, the second radio frequency signal, and the third radio frequency signal to generate a radio frequency output signal using the combiner, and providing the radio frequency output signal at a fourth terminal of the combiner.

19. The method of claim 18 further comprising activating the peaking amplifier at a first power threshold, and activating the load modulating amplifier at a second power threshold greater than the first power threshold.

20. The method of claim 19 wherein activating the load modulating amplifier includes modulating down a load of the carrier amplifier and of the peaking amplifier.
